(19) United States
(12) Patent Application Publication
(10) Pub. No.: US 2021/0375814 A1
(43) Pub. Date: Dec. 2, 2021

(54) INTEGRATED CIRCUIT MODULE STRUCTURE AND METHOD FOR MANUFACTURING SAME

(71) Applicant: ANHUI YUNTA ELECTRONIC TECHNOLOGIES CO., LTD., Ningguo (CN)

(72) Inventors: Chengjie Zuo, Ningguo (CN); Jun He, Ningguo (CN)

(73) Assignee: ANHUI YUNTA ELECTRONIC TECHNOLOGIES CO., LTD., Ningguo (CN)

(21) Appl. No.: 16/763,899

(22) PCT Filed: May 22, 2018
(86) PCT No.: PCT/CN2018/087885

§ 371 Date: May 13, 2020

(30) Foreign Application Priority Data
Dec. 6, 2017 (CN) 201711278627.3
Dec. 6, 2017 (CN) 201721681899.3

(51) Int. Cl. H01L 23/00; H01L 23/31; H01L 21/56

(52) U.S. Cl. CPC H01L 24/20; H01L 24/19; H01L 2224/215; H01L 21/565; H01L 2224/2101; H01L 23/3185

(57) ABSTRACT

Disclosed are an integrated circuit module structure and a method for manufacturing the same. The integrated circuit module structure includes an integrated device, a molding layer, at least one redistribution layer and at least one insulating layer. At least one interface that is connected to a first functional circuit is disposed in a first face of the integrated device. The molding layer exposes the at least one interface of the integrated device. Each redistribution layer includes at least one metal pattern, and at least one metal pattern is correspondingly connected to the at least one interface. The at least one metal pattern forms a second functional circuit, or the at least one metal pattern is directly connected to a second functional circuit. The at least one insulating layer is located on a side, close to the first face, of the integrated device and the molding layer, each insulating layer covers one redistribution layer, and the insulating layer exposing a part of the at least one metal pattern.

### CROSS-REFERENCES TO RELATED APPLICATION

This is a National stage application, filed under 37 U.S.C. 371, of International Patent Application NO. PCT/CN2018/087885, filed on May 22, 2018, which is based on and claims priority to a Chinese patent application No. 201711278627.3 filed on Dec. 6, 2017, and a Chinese patent application No. 201721681899.3 filed on Dec. 6, 2017, disclosures of which are incorporated herein by reference in entirety their entireties.

### TECHNICAL FIELD

The present disclosure relates to integrated circuit module technology, for example, to an integrated circuit module structure and a method for manufacturing the same.

### BACKGROUND

With the increasing development of electronic products, the research and development of various components are moving towards integration and multifunctionality. Therefore, requirements for an integrated circuit module structure for an integrated device are also increasing.

When an integrated device is assembled in a System in Package (SIP) module, it is necessary to provide pads and solder balls connected to the pads in the integrated circuit module structure so as to enable connection between the integrated circuit device/chip and other integrated circuit devices/chips. The solder balls have a parasitic resistance of about 30 mΩ, and the parasitic resistance of the solder balls can be ignored during the packaging of digital chips in the related art. However, in RF modules or high-frequency applications, the parasitic resistance of solder balls may significantly reduce the quality factor of a capacitor or an inductor in an integrated device, thereby affecting the performance of the integrated device.

### SUMMARY

The present disclosure provides an integrated circuit module structure and a method for manufacturing the same, which aims to reduce the parasitic resistance, improve the quality factor of a capacitor or an inductor in an integrated device and optimize the performance of the integrated device.

The present disclosure provides an integrated circuit module structure. The integrated circuit module structure includes: an integrated device, a first functional circuit being disposed in the integrated device, the integrated device comprising opposite first and second faces, and at least one interface that is connected to the first functional circuit being disposed in the first face; a molding layer, the molding layer covering a part of a surface of the integrated device and exposing the at least one interface of the integrated device; at least one redistribution layer, each of the at least one redistribution layer comprising at least one metal pattern, and at least one metal pattern of one of the at least one redistribution layer closest to the first face being correspondingly connected to the at least one interface, wherein the at least one metal pattern of the one of the at least one redistribution layer closest to the first face forms a second functional circuit, or the at least one metal pattern of the one of the at least one redistribution layer closest to the first face is directly connected to a second functional circuit; and at least one insulating layer that covers the molding layer and the at least one redistribution layer, each of the at least one insulating layer covering one of the at least one redistribution layer, and one of the at least one insulating layer farthest from the first face exposing a part of at least one metal pattern of one of the at least one redistribution layer closest to the one of the at least one insulating layer farthest from the first face.

In one embodiment, each of the at least one metal pattern of the one of the at least one redistribution layer closest to the first face covers and contacts one of the at least one interface corresponding to the each of the at least one metal pattern of the one of the at least one redistribution layer closest to the first face, and the each of the at least one metal pattern of the one of the at least one redistribution layer closest to the first face has an area larger than an area of the one of the at least one interface corresponding to the each of the at least one metal pattern of the one of the at least one redistribution layer closest to the first face.

In one embodiment, more than one integrated device is provided, and interfaces of the more than one integrated device are connected through the at least one metal pattern of the one of the at least one redistribution layer closest to the first face.

In one embodiment, a plurality of redistribution layers are provided, and the plurality of redistribution layers are separated from each other by the at least one insulating layer and electrically connected to each other by one or more through holes in the at least one insulating layer.

The present disclosure further provides a method for manufacturing an integrated circuit module structure. The method includes: providing a support plate and forming a transition glue on the support plate; disposing an integrated device on the transition glue, a first functional circuit being disposed in the integrated device, the integrated device including opposite first and second faces, at least one interface that is connected to the first functional circuit being disposed in the first face, and the second face being in contact with the transition glue; forming a molding layer on the transition glue, the molding layer covering the integrated device; thinning the molding layer to expose the at least one interface; forming at least one redistribution layer on the molding layer, each of the at least one redistribution layer including at least one metal pattern, and at least one metal pattern of the one of the at least one redistribution layer closest to the first face being correspondingly connected to the at least one interface, where the at least one metal pattern of the one of the at least one redistribution layer closest to the first face forms a second functional circuit, or the at least one metal pattern of the one of the at least one redistribution layer closest to the first face is directly connected to a second functional circuit; and forming at least one insulating layer on the molding layer and the at least one redistribution layer, each of the at least one insulating layer covering one of the at least one redistribution layer, and one of the at least one insulating layer farthest from the first face exposing a part of at least one metal pattern of one of the at least one redistribution layer closest to the one of the at least one insulating layer farthest from the first face.

In one embodiment, after forming the at least one insulating layer, the method further includes: removing the support plate and the transition glue.

In one embodiment, the at least one metal pattern of the one of the at least one redistribution layer closest to the first face is formed on the molding layer by using a redistribution technology, each of the at least one metal pattern covers and contacts one of the at least one interface corresponding to the each of the at least one metal pattern of the one of the at least one redistribution layer closest to the first face, and the each of the at least one metal pattern of the one of the at least one redistribution layer closest to the first face has an area larger than an area of the one of the at least one interface corresponding to the each of the at least one metal pattern of the one of the at least one redistribution layer closest to the first face.

In one embodiment, a material of the at least one metal pattern of the one of the at least one redistribution layer closest to the first face is copper.

In one embodiment, forming the at least one insulating layer on the molding layer and the at least one redistribution layer, each of the at least one insulating layer covering one of the at least one redistribution layer, includes: forming a plurality of redistribution layers on the molding layer, the plurality of redistribution layers being separated from each other by the at least one insulating layer and electrically connected to each other by one or more through holes in the at least one insulating layer.

In one embodiment, forming the at least one insulating layer on the molding layer and the at least one redistribution layer, each of the at least one insulating layer covering one of the at least one redistribution layer, and one of the at least one insulating layer farthest from the first face exposing a part of the at least one metal pattern of one of the at least one redistribution layer closest to the one of the at least one insulating layer farthest from the first face, includes: depositing at least one dielectric material layer on the molding layer and the at least one redistribution layer, each of the at least one dielectric material layer covering one of the at least one redistribution layer, and the at least one dielectric material layer covering the at least one metal pattern and the integrated device; and etching one of the at least one dielectric material layer farthest from the first face to expose a part of at least one metal pattern of the one of the at least one redistribution layer closest to the one of the at least one insulating layer farthest from the first face.

In the integrated circuit module structure and the method for manufacturing the same provided by embodiments of the present application, a metal pattern corresponding to an interface of the integrated device is disposed on the interface so that a second functional circuit or a direct electrical connection to a second functional circuit is achieved. Such configuration eliminates the need to use intermediate materials such as solder balls and copper pillars, thereby solving the problem of great reduction in quality factor of the capacitor or inductor in the integrated device due to the parasitic resistance caused by solder balls and the like in the related art, reducing the parasitic resistance, improving the quality factor of the capacitor or inductor in the integrated device and optimizing the performance of the integrated device.

### BRIEF DESCRIPTION OF DRAWINGS

FIG. 1 is a structure diagram of an integrated circuit module structure according to a first embodiment.

FIG. 2 is a structure diagram of another integrated circuit module structure according to the first embodiment.

FIG. 3 is a structure diagram of still another integrated circuit module structure according to the first embodiment.

FIG. 4 is a flowchart of a method for manufacturing an integrated circuit module structure according to a second embodiment.

FIG. 5 is a structure diagram corresponding to the method for manufacturing the integrated circuit module structure according to the second embodiment.

### DETAILED DESCRIPTION

The present disclosure will be further described with reference to the accompanying drawings and embodiments. It is to be understood that the embodiments set forth below are intended to illustrate and not to limit the present disclosure. It is to be noted that to facilitate description, only part, not all, of structures related to the present disclosure are illustrated in the accompanying drawings.

### First Embodiment

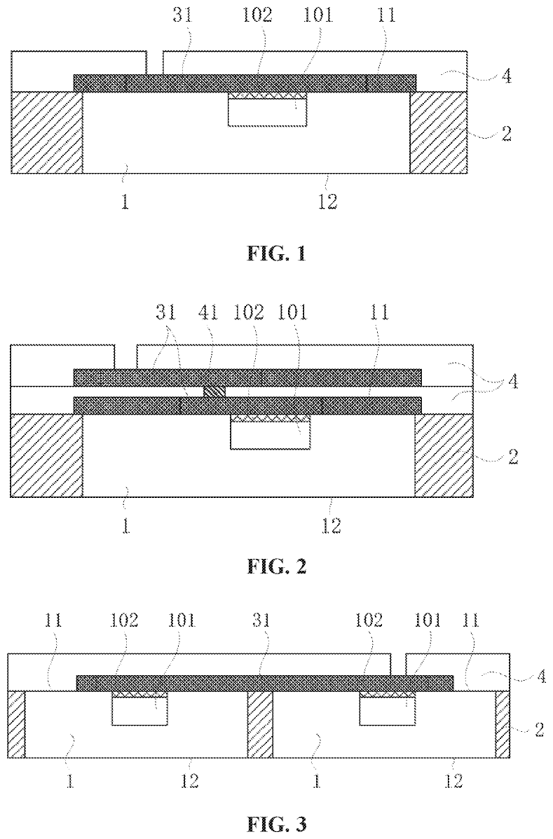

FIG. 1 is a structure diagram of an integrated circuit module structure according to the first embodiment. Referring to FIG. 1, the integrated circuit module structure includes an integrated device 1, a molding layer 2 for packaging the integrated device 1, a redistribution layer, and an insulating layer 4. A first functional circuit 101 is disposed in the integrated device 1, the integrated device 1 includes a first face 11 and a second face 12 opposite to each other, and at least one interface 102 that is connected to the first functional circuit 101 is disposed in the first face 11. The molding layer 2 covers a part of a surface of the integrated device 1 and exposes the at least one interface 102 of the integrated device 1. The redistribution layer includes at least one metal pattern 31, and the at least one metal pattern 31 is correspondingly connected to the at least one interface 102, where the metal pattern 31 forms a second functional circuit by itself, or the metal pattern 31 is directly connected to a second functional circuit. The at least one insulating layer 4 covers the molding layer and the at least one redistribution layer, and is located a side, close to the first face 11, of the integrated device 1 and the molding layer 2. The insulating layer 4 covers the redistribution layer, and the insulating layer 4 exposes a part of the at least one metal pattern 31 to form one or more pads.

It is to be noted that the integrated device 1 may be, but is not limited to, a chip, and may also be a surface mount device, or a structure formed when the two are used in combination or other structures.

The metal pattern 31 correspondingly connected to the interface 102 may forms a second functional circuit by itself to constitute a complete functional circuit with the first functional circuit 101 in the integrated device 1. Exemplarily, the metal pattern 31 itself may forms a second functional circuit (other structures such as an inductor), and may be combined with a first functional circuit 101 (such as a capacitor) in the integrated device to constitute a complete functional circuit so as to achieve a certain function (such as filtering). Alternatively, the metal pattern 31 may be a functional circuit in the first functional circuit 101 that needs to be connected to an external circuit. For example, the metal pattern 31 is a metal electrode plate, which forms a complete capacitor with the first functional circuit 101 to constitute a complete functional circuit so as to achieve a specific function. The metal pattern 31 may also be directly connected to a second functional circuit. Exemplarily, the first functional circuit 101 (such as a capacitor) in the integrated device 1 is combined with a second functional circuit (such as an inductor) outside the integrated device 1 to constitute a complete functional circuit so as to achieve a certain function (such as filtering), and the metal pattern 31 may be directly connected to the second functional circuit (such as the inductor) to allow the two functional circuits to constitute a complete functional circuit. The metal pattern 31 is a second functional circuit or directly connected to a second functional circuit so that the parasitic resistance in the integrated circuit module structure can be reduced.

To protect the integrated device 1 from erosion of water and oxygen, the integrated device 1 may be packaged with a molding layer 2. The first face 11 of the integrated device 1 where the at least one interface 102 is located is not covered by the molding layer 2 to allow the at least one interface 102 to be connected to the at least one metal pattern 31 in the redistribution layer. To make the parasitic resistance of the at least one metal pattern 31 in the redistribution layer smaller, the at least one metal pattern 31 may be made of a metal material having high conductivity, such as copper.

The insulating layer 4 may be formed on a side, close to the first face 11, of the integrated device 1 and the molding layer 2 by a deposition method. The deposited insulating layer 4 is not easy to be separated from the integrated device 1, the molding layer 2 and the redistribution layer, and may replace a substrate in the related art. Therefore, it is not necessary to introduce, in the integrated circuit module structure, solder balls for welding the integrated device 1 to a substrate, thereby avoiding the involvement of intermediate materials such as solder balls and copper pillars and eliminating the influence of the parasitic resistance generated by the solder balls and copper pillars on the quality factor of the capacitance or inductance of the integrated device 1 in the RF modules or high-frequency applications. Meanwhile, the insulating layer 4 is thinner and more accurate than a substrate in the related art, which makes the integrated circuit module structure smaller and more compact and enables higher integration level of the overall system. In addition, close adhesion of the insulating layer 4 to the integrated device 1, the molding layer 2 and the redistribution layer can also play a certain role of molding to protect the integrated device 1 from erosion. To enable the integrated circuit module structure to be connected to other integrated circuit module structures, printed circuit boards or other structures, a part of the at least one metal pattern 31 may be exposed from the insulating layer 4 to form one or more pads, so that the integrated circuit module structure can be connected to external circuits through the one or more pads.

It is to be noted that both the number of insulating layers and the number of redistribution layers may be one or more. FIG. 2 is a structure diagram of another integrated circuit module structure according to the first embodiment. Referring to FIG. 2, optionally, there are a plurality of redistribution layers that are separated from each other by insulating layers 4 and electrically connected to each other by one or more through holes 41.

When the number of redistribution layers is more than one, the number of insulating layers 4 is also more than one, and the plurality of redistribution layers are separated by the insulating layers 4 to avoid a short circuit and the like. It is to be understood that at least one metal pattern 31 of one redistribution layer is ensured to be in contact with the at least one interface 102 of the integrated device 1, but both the number of insulating layers 4 and the number of redistribution layers are not limited. A through hole 41 may be opened in an insulating layer 4 between the redistribution layers to achieve electrical connection between the metal patterns 31 of the plurality of redistribution layers.

In the integrated circuit module structure provided in the embodiment of the present application, at least one interface 102 connected to the first functional circuit 101 in the first face 11 of the integrated device 1 is disposed in the first face 11 of the integrated device 1, the first face 11 of the integrated device 1 is exposed from the molding layer 2, the at least metal pattern 31 of the redistribution layer is correspondingly connected to the at least one interface 102, the at least one insulating layer 4 is formed on a side of the integrated device 1 and the molding layer 2 close to the first face 11, and a part of the at least one metal pattern 31 is exposed from the insulating layer 4 to form one or more pads. Such configuration eliminates the need to use intermediate materials such as solder balls and copper pillars, thereby solving the problem of great reduction in quality factor of the capacitor or inductor in the integrated device due to the parasitic resistance caused by solder balls and the like, avoiding the involvement of solder balls, reducing the parasitic resistance, improving the quality factor of the capacitor or inductor in the integrated device and optimizing the performance of the integrated device.

In one embodiment, each metal pattern 31 covers and contacts one of the at least one interface 102 corresponding to the each metal pattern 31, and each metal pattern 31 has an area larger than an area of its corresponding interface 102.

To ensure that each metal pattern 31 and its corresponding interface 102 can be effectively connected to form a path with an external circuit, the corresponding interface 102 may be completely or partially covered by the each metal pattern 31. There may also be a very small parasitic resistance in the at least one metal pattern 31 in practical applications. Thus, in order for the parasitic resistance in the at least one metal pattern 31 to be reduced and prevented from reducing the quality factor of the capacitor or inductor in the integrated device in the RF modules or high-frequency applications, the area of each metal pattern 31 can be appropriately enlarged. Optionally, each of the at least one metal pattern 31 has an area larger than an area of one of the at least one interface 102 corresponding to the each of the at least one metal pattern 31.

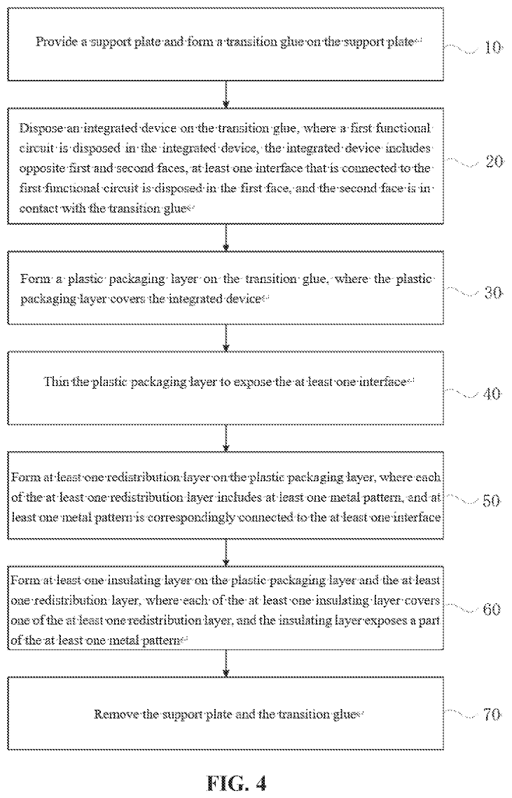

FIG. 3 is a structure diagram of still another integrated circuit module structure according to the first embodiment. Referring to FIG. 3, optionally, the number of integrated devices 1 is more than one, and interfaces 102 of the plurality of integrated devices 1 are connected by a metal pattern 31.

It is to be understood that in some integrated circuit module structures, more than one integrated device 1 needs to be provided, and a plurality of integrated devices 1 with the same function or different functions may be provided to achieve the effect of multifunctionality and high integration. When the number of integrated devices 1 is more than one and the integrated devices 1 need to be connected to each other, interfaces 102 of the plurality of integrated devices 1 may be connected by one or more metal pattern 31. When all integrated devices 1 need to be connected together, they may be connected by one metal pattern 31 with a sufficiently large area. When the plurality of integrated devices 1 have special connection relationships, they may also be connected by a plurality of independent metal patterns 31.

The insulating layer 4 may expose a part of the at least one metal pattern 31 to form one or more pads. The formed one or more pads are to be connected to other external integrated circuit module structures, printed circuit boards or other structures. To avoid an unnecessary short circuit and the like from occurring in connecting of the pads formed in the plurality of metal patterns 31 of the redistribution layer to other structures, the insulating layer 4 may be a dielectric material layer.

### Second Embodiment

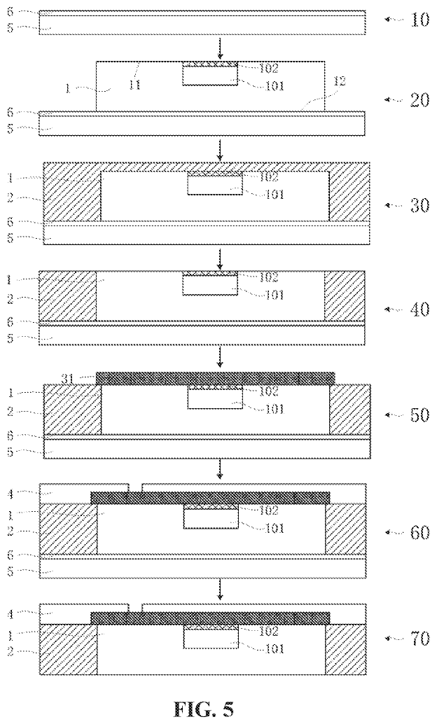

FIG. 4 is a flowchart of a method for manufacturing an integrated circuit module structure according to the second embodiment. FIG. 5 is a structure diagram corresponding to the method for manufacturing the integrated circuit module structure according to the second embodiment. Referring to FIGS. 4 and 5, the method for manufacturing the integrated circuit module structure includes the steps described below.

In step 10, a support plate 5 is provided, and a transition glue 6 is formed on the support plate 5.

In step 20, an integrated device 1 is disposed on the transition glue 6, where a first functional circuit 101 is disposed in the integrated device 1, the integrated device 1 includes a first face 11 and a second face 12 opposite to each other, at least one interface 102 that is connected to the first functional circuit 101 is disposed in the first face 11, and the second face 12 is in contact with the transition glue 6.

In the process of manufacturing the integrated circuit module structure, the support plate 5 provides a manufacturing platform. The transition glue 6 is formed on the support plate 5 so that the integrated device 1 can be fixedly disposed on the transition glue 6 to prevent the integrated device 1 from shifting or tilting in the subsequent manufacturing process. The first face 11 of the integrated device 1 provided with the interface 102 that is connected to the first functional circuit 101 is placed on a side away from the transition glue 6, and the second face 12 of the integrated device 1 is brought into contact with the transition glue 6.

In step 30, a molding layer 2 is formed on the transition glue, and the molding layer 2 covers the integrated device 1.

To prevent the integrated device 1 from erosion of water and oxygen, which affects the performance of the integrated device 1, the integrated device 1 is plastic-packaged. Since the integrated device 1 is disposed on the transition glue 6, a molding layer 2 is formed on the transition glue 6 to cover the integrated device 1 so as to ensure the sealing of the integrated device 1.

In step 40, the molding layer 2 is thinned to expose the at least one interface 102.

Since the integrated device 1 needs to be connected to an external circuit to allow the first functional circuit 101 to work properly, the molding layer 2 on the side of the first face 11 where the interface 102 connected to the first functional circuit 101 in the integrated device 1 is located is correspondingly thinned. For example, the at least one interface 102 may be exposed from the molding layer 2 by grinding the molding layer 2.

To expose the at least one interface 102, the molding layer 2 needs to be thinned. The molding layer 2 may be thinned in various ways. Exemplarily, the molding layer 2 may be polished to expose the first face 11 of the integrated device 1 where the interface 102 is located. It is to be understood that in order to expose the at least one interface 102, the molding layer 2 may also be thinned by other methods such as chemical etching and wet grinding.

In step 50, at least one redistribution layer is formed on the molding layer 2, each redistribution layer includes at least one metal pattern 31, and at least one metal pattern 31 of a redistribution layer closest to the first face is correspondingly connected to the at least one interface 102, where the at least one metal pattern 31 of the redistribution layer closest to the first face forms a second functional circuit, or the at least one metal pattern 31 of the redistribution layer closest to the first face is directly connected to a second functional circuit.

To facilitate connection between the at least one interface 102 and other external structures, at least one metal pattern 31 correspondingly connected to the at least one interface 102 is formed on the molding layer 2. For example, the at least one metal pattern 31 is formed by deposition of a metal layer, exposure, development and other processes, and the number of metal patterns 31 is one or more. In addition, to reduce the parasitic resistance in the integrated circuit module structure as much as possible, the at least one metal pattern 31 is made of a metal material with high conductivity, and under the premise of ensuring the normal operation of the at least one metal pattern 31, the at least one metal pattern 31 may be made as large as possible.

In step 60, at least one insulating layer 4 is formed on the molding layer 2 and the at least one redistribution layer, each insulating layer 4 covers one of the at least one redistribution layer, and an insulating layer 4 farthest from the first face exposes a part of at least one metal pattern 31 of a redistribution layer closest to the insulating layer 4 farthest from the first face.

Since the at least one metal pattern 31 has a large area and the at least one interface 102 of the integrated device 1 is exposed outside the molding layer 2, when the integrated circuit module structure is connected to an external circuit, in order to avoid an unnecessary short circuit and the like between the at least one metal pattern 31 or interface 102 and the external circuit, an insulating layer 4 is formed on the molding layer 2 and the at least one metal pattern 31. When the insulating layer 4 is formed, a part of the at least one metal pattern 31 is exposed from the insulating layer 4. The exposed part of the at least one metal pattern 31 forms one or more pads for connecting the integrated circuit module structure to the external circuit(s). It is to be noted that the insulating layer 4 may be formed by a deposition method, and the insulating layer 4 can have good adhesion to the integrated device 1, the at least one metal pattern 31 and the molding layer 2. Therefore, on one hand, the insulating layer 4 can play a certain degree of sealing to protect the integrated device 1 from erosion of water and oxygen, and on the other hand, welding the insulating layer 4 to the integrated device 1 or the at least one metal pattern 31 by solder balls can also avoided, so that it is no longer necessary to introduce the solder balls with large parasitic resistance in the integrated circuit module structure.

It is to be noted that both the number of insulating layers 4 and the number of redistribution layers may be one or more. Exemplarily, a plurality of redistribution layers are formed on the molding layer 2, and they are separated from each other by a plurality of insulating layers 4 and electrically connected to each other by one or more through holes 41 in the insulating layers 4.

When the number of redistribution layers is more than one, the number of insulating layers 4 is also more than one, so that the plurality of redistribution layers are separated by the insulating layers 4 to avoid a short circuit and like. A through hole 41 may be opened in an insulating layer 4 between the redistribution layers to expose a part of the at least one metal pattern 31, so that the metal patterns 31 in the plurality of redistribution layers can be electrically connected.

A dielectric material layer may be deposited and formed on the molding layer 2, and the formed dielectric material layer covers the at least one metal patterns 31 and the integrated device 1. The dielectric material layer is etched to expose a part of the at least one metal pattern 31.

To achieve good adhesiveness between the insulating layer 4 and the molding layer 2 to ensure the insulating performance of the insulating layer 4, a dielectric material layer with good insulating performance may be formed by a deposition method. The formed dielectric material layer covers the at least one metal pattern 31 and the integrated device 1, which can protect the integrated device 1 from erosion and avoid an unnecessary short circuit and the like. In order to connect the at least one metal pattern 31 to an external circuit, a part of the at least one metal pattern 31 is exposed by etching the dielectric material layer.

In the method for manufacturing the integrated circuit module structure provided by the embodiments of the present application, the need to use intermediate materials such as solder balls and copper pillars is eliminated, which greatly reduces parasitic resistance, solves the problem of great reduction in quality factor of the capacitor or inductor in the integrated device due to the parasitic resistance caused by solder balls and the like, avoids the introduction of solder balls, reduces the parasitic resistance, improves the quality factor of the capacitor or inductor in the integrated device 1 and optimizes the performance of the integrated device 1.

In one embodiment, after forming the at least one insulating layer 4, the method further includes a step 70: removing the support plate 5 and the transition glue 6.

Since the support plate 5 only provides a manufacturing platform in the process of manufacturing the integrated circuit module structure, the transition glue 6 is only for fixing the integrated device 1 and the two are not packaged in the integrated circuit module structure, after the at least one insulating layer 4 is formed, the transition glue 6 may be removed by a method such as high temperature. After the transition glue 6 is removed, the support plate 5 can fall off naturally. The support plate 5 can be recycled for manufacturing the next batch of integrated circuit module structures. Therefore, the method for manufacturing the integrated circuit module structure provided in the embodiment of the present application can also save costs.

In one embodiment, the at least one metal pattern 31 may be formed on the molding layer by using a redistribution technology, and the formed at least one metal pattern 31 covers and contacts the at least one interface 102 corresponding to the at least one metal pattern 31, and each of the at least one metal pattern 31 has an area larger than an area of one of the at least one interface 102 corresponding to the each of the at least one metal pattern 31.

Through adopting the redistribution technology, the original design of line connection point positions can be changed to improve the added value of the original design, and the interval between the line connection point positions can be increased to provide larger bump areas, which reduces the stress between the insulating layer 4 and the integrated device 1 and increases the reliability of the integrated device 1. Therefore, the at least one metal pattern 31 can be formed on the molding layer 2 exposing the at least one interface 102 by the redistribution technology. To enable each of the at least one metal pattern 31 to be effectively connected to one of the at least one interface 102, the one of the at least one interface 102 may be partially or completely covered by the each of the at least one metal pattern 31. To reduce the parasitic resistance in the integrated circuit module structure and to ensure effective contact between the at least one metal pattern 31 and the at least one interface 102, each of the at least one metal pattern 31 has an area larger than an area of one of the at least one interface 102 corresponding to the each of the at least one metal pattern 31.

There may also be a parasitic resistance in the at least one metal pattern 31. Thus, to reduce the parasitic resistance in the at least one metal pattern 3, the at least one metal pattern 31 may be made of a metal material with high conductivity, and a material of the at least one metal pattern 31 may be copper.

### INDUSTRIAL APPLICABILITY

Embodiments of the present application provide an integrated circuit module structure and a method for manufacturing the same, which solves the problem of great reduction in quality factor of the capacitor or inductor in the integrated device due to the parasitic resistance caused by solder balls and the like, reduces the parasitic resistance, improves the quality factor of the capacitor or inductor in the integrated device and optimizes the performance of the integrated device.

1. An integrated circuit module structure, comprising:
an integrated device, a first functional circuit being disposed in the integrated device, the integrated device comprising opposite first and second faces, and at least one interface that is connected to the first functional circuit being disposed in the first face;
a molding layer, the molding layer covering a part of a surface of the integrated device and exposing the at least one interface of the integrated device;
at least one redistribution layer, each of the at least one redistribution layer comprising at least one metal pattern, and at least one metal pattern of one of the at least one redistribution layer closest to the first face being correspondingly connected to the at least one interface, wherein the at least one metal pattern of the one of the at least one redistribution layer closest to the first face forms a second functional circuit, or the at least one metal pattern of the one of the at least one redistribution layer closest to the first face is directly connected to a second functional circuit; and
at least one insulating layer that covers the molding layer and the at least one redistribution layer, each of the at least one insulating layer covering one of the at least one redistribution layer, and one of the at least one insulating layer farthest from the first face exposing a part of the at least one metal pattern of one of the at least one redistribution layer closest to the one of the at least one insulating layer farthest from the first face.

2. The integrated circuit module structure of claim 1, wherein each of the at least one metal pattern of the one of the at least one redistribution layer closest to the first face covers and contacts one of the at least one interface corresponding to the each of the at least one metal pattern of the one of the at least one redistribution layer closest to the first face, and the each of the at least one metal pattern of the one of the at least one redistribution layer closest to the first face has an area larger than an area of the one of the at least one interface corresponding to the each of the at least one metal pattern of the one of the at least one redistribution layer closest to the first face.

3. The integrated circuit module structure of claim 1, wherein more than one integrated device is provided, and interfaces of the more than one integrated device are connected through the at least one metal pattern of the one of the at least one redistribution layer closest to the first face.

4. The integrated circuit module structure of claim 1, wherein a plurality of redistribution layers are provided, and the plurality of redistribution layers are separated from each other by the at least one insulating layer and electrically connected to each other by one or more through holes in the at least one insulating layer.

5. A method for manufacturing an integrated circuit module structure, comprising:
providing a support plate and forming a transition glue on the support plate;
disposing an integrated device on the transition glue, a first functional circuit being disposed in the integrated device, the integrated device comprising opposite first and second faces, at least one interface that is connected to the first functional circuit being disposed in the first face, and the second face being in contact with the transition glue;
forming a molding layer on the transition glue, the molding layer covering the integrated device;
thinning the molding layer to expose the at least one interface;
forming at least one redistribution layer on the molding layer, each of the at least one redistribution layer comprising at least one metal pattern, and at least one metal pattern of one of the at least one redistribution layer closest to the first face being correspondingly connected to the at least one interface, wherein the at least one metal pattern of the one of the at least one redistribution layer closest to the first face forms a second functional circuit, or the at least one metal pattern of the one of the at least one redistribution layer closest to the first face is directly connected to a second functional circuit; and
forming at least one insulating layer on the molding layer and the at least one redistribution layer, each of the at least one insulating layer covering one of the at least one redistribution layer, and one of the at least one insulating layer farthest from the first face exposing a part of the at least one metal pattern of one of the at least one redistribution layer closest to the one of the at least one insulating layer farthest from the first face.

6. The method for manufacturing the integrated circuit module structure of claim 5, wherein after forming the at least one insulating layer, the method further comprises: removing the support plate and the transition glue.

7. The method for manufacturing the integrated circuit module structure of claim 5, wherein the at least one metal pattern of the one of the at least one redistribution layer closest to the first face is formed on the molding layer by using a redistribution technology, each of the at least one metal pattern of the one of the at least one redistribution layer closest to the first face covers and contacts one of the at least one interface corresponding to the each of the at least one metal pattern of the one of the at least one redistribution layer closest to the first face, and the each of the at least one metal pattern of the one of the at least one redistribution layer closest to the first face has an area larger than an area of the one of the at least one interface corresponding to the each of the at least one metal pattern of the one of the at least one redistribution layer closest to the first face.

8. The method for manufacturing the integrated circuit module structure of claim 7, wherein a material of the at least one metal pattern of the one of the at least one redistribution layer closest to the first face is copper.

9. The method for manufacturing the integrated circuit module structure of claim 5, wherein forming the at least one insulating layer on the molding layer and the at least one redistribution layer, each of the at least one insulating layer covering one of the at least one redistribution layer, comprises:
forming a plurality of redistribution layers on the molding layer, the plurality of redistribution layers being separated from each other by the at least one insulating layer and electrically connected to each other by one or more through holes in the at least one insulating layer.

10. The method for manufacturing the integrated circuit module structure of claim 5, wherein forming the at least one insulating layer on the molding layer and the at least one redistribution layer, each of the at least one insulating layer covering one of the at least one redistribution layer, and the one of the at least one insulating layer farthest from the first face exposing a part of the at least one metal pattern of the one of the at least one redistribution layer closest to the one of the at least one insulating layer farthest from the first face, comprises:
depositing at least one dielectric material layer on the molding layer and the at least one redistribution layer, each of the at least one dielectric material layer covering one of the at least one redistribution layer, and the at least one dielectric material layer covering the at least one metal pattern and the integrated device; and
etching one of the at least one dielectric material layer farthest from the first face to expose a part of at least one metal pattern of the one of the at least one redistribution layer closest to the one of the at least one insulating layer farthest from the first face.
